(19) United States
(12) Patent Application Publication
(10) Pub. No.: US 2023/0275119 A1
(43) Pub. Date: Aug. 31, 2023

(54) TRANSFORMER ELEMENT, SEMICONDUCTOR DEVICE, METHOD OF MANUFACTURING TRANSFORMER ELEMENT, AND METHOD OF MANUFACTURING SEMICONDUCTOR DEVICE

(71) Applicant: Mitsubishi Electric Corporation, Tokyo (JP)

(72) Inventors: Yasuo YAMAGUCHI, Tokyo (JP); Manabu YOSHINO, Tokyo (JP); Toshihiro IMASAKA, Tokyo (JP); Yohei TORII, Tokyo (JP)

(73) Assignee: Mitsubishi Electric Corporation, Tokyo (JP)

(21) Appl. No.: 18/062,316

(22) Filed: Dec. 6, 2022

(30) Foreign Application Priority Data
Feb. 25, 2022 (JP) 2022-028032

(51) Int. Cl. H01L 49/02

(52) U.S. Cl. CPC H01L 28/10

(57) ABSTRACT

To provide a transformer element in which pads for wire bonding are made thick while suppressing influence on coil characteristics. A transformer element includes a first coil having a planner shape, a first insulating film provided on an upper side of the first coil, a second coil having a planner shape opposite to the first coil provided on the first insulating film, a first pad provided on the first insulating film and connected to a side of one end of the second coil, a second pad provided on the first pad, and a second insulating film provided on the first insulating film and the second coil so as to cover the second coil, in which an aggregate thickness of the first pad and the second pad is thicker than the second coil, and the second pad at least partially covers the second insulating film.

### BACKGROUND OF THE INVENTION

### Field of the Invention

The present disclosure relates to a transformer element, a semiconductor device, a method of manufacturing a transformer element, and a method of manufacturing a semiconductor device.

### Description of the Background Art

International Publication No. 2014/155478 discloses a semiconductor device including two coils that are magnetically coupled to each other.

By thickening a wire bonding pad of the coil formed on the upper side of the insulating film that insulates between the coils, the operability level of wire bonding to the pad improves. In the conventional technology, however, thickening the pad without affecting the coil characteristics has been difficult to implement.

### SUMMARY

An object of the present disclosure is to provide a transformer element in which pads are made thick while suppressing influence on coil characteristics, and a method of manufacturing a transformer element in which a pad or pads are made thick while suppressing influence on coil characteristics.

In an aspect of the present disclosure, a transformer element includes a first coil having a planner shape, a first insulating film provided on an upper side of the first coil, a second coil having a planner shape and opposite to the first coil and provided on the first insulating film, a first pad provided on the first insulating film and connected to a side of one end of the second coil, a second pad provided on the first pad, and a second insulating film provided on the first insulating film and the second coil so as to cover the second coil. An aggregate thickness of the first pad and the second pad is thicker than the second coil, and the second pad at least partially covers the second insulating film.

In an aspect of the present disclosure, in a method of manufacturing a transformer element, the transformer element includes a first coil having a planner shape, a first insulating film provided on an upper side of the first coil, a second coil having a planner shape and opposite to the first coil and provided on the first insulating film, a first pad provided on the first insulating film and connected to a side of one end of the second coil, a second pad provided on the first pad, and a second insulating film provided on the first insulating film and the second coil so as to cover the second coil. The method includes forming the second coil on the first insulating film, and then forming the second insulating film on the first insulating film and the second coil such that the second coil is covered and the first pad is not covered at least partially. The method also includes forming the second pad on the first pad after forming the second insulating film.

The present disclosure is to provide a transformer element in which pads are made thick while suppressing influence on coil characteristics, and a method of manufacturing a transformer element in which the pad or pads are made thick while suppressing influence on coil characteristics.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a transformer element of a first embodiment;

FIG. 2 is a cross-sectional view illustrating a transformer element of a modification example of the first embodiment;

FIG. 3 is a cross-sectional view illustrating a transformer element of an other modification example of the first embodiment;

FIG. 4 is a cross-sectional view illustrating a transformer element of a comparative example;

FIG. 5 is a diagram illustrating a state during manufacturing in a method of manufacturing the transformer element according to the first embodiment;

FIG. 6 is a diagram illustrating a state during manufacturing in the method of manufacturing the transformer element according to the first embodiment;

FIG. 7 is a diagram illustrating a state during manufacturing in the method of manufacturing the transformer element according to the first embodiment;

FIG. 8 is a diagram illustrating a state during manufacturing in the method of manufacturing the transformer element according to the first embodiment;

FIG. 9 is a diagram illustrating a state during manufacturing in the method of manufacturing the transformer element according to the first embodiment;

FIG. 10 is a diagram illustrating a state during manufacturing in the method of manufacturing the transformer element according to the first embodiment;

FIG. 11 is a diagram illustrating a state during manufacturing in a method of manufacturing a transformer element according to a second embodiment;

FIG. 12 is a diagram illustrating a state during manufacturing in the method of manufacturing the transformer element according to the second embodiment;

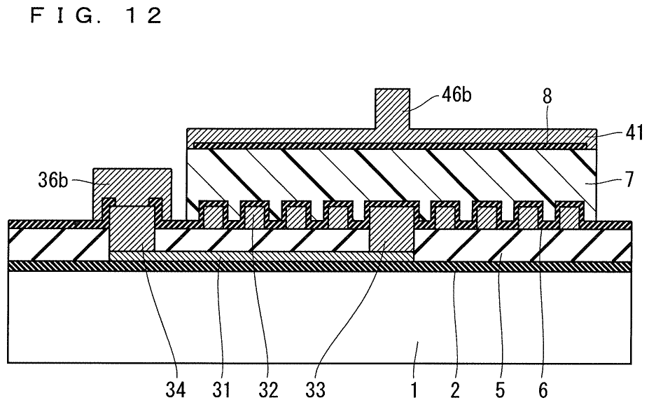

FIG. 13 is a cross-sectional view illustrating the transformer element of the second embodiment;

FIG. 14 is a diagram illustrating a state during manufacturing in a method of manufacturing a transformer element according to a third embodiment;

FIG. 15 is a diagram illustrating a state during manufacturing in the method of manufacturing the transformer element according to the third embodiment;

FIG. 16 is a diagram illustrating a state during manufacturing in the method of manufacturing the transformer element according to the third embodiment;

FIG. 17 is a diagram illustrating a state during manufacturing in the method of manufacturing the transformer element according to the third embodiment;

FIG. 18 is a diagram illustrating a state during manufacturing in the method of manufacturing the transformer element according to the third embodiment;

FIG. 19 is a diagram illustrating a state during manufacturing in the method of manufacturing the transformer element according to the third embodiment;

FIG. 20 is a diagram illustrating a state during manufacturing in the method of manufacturing the transformer element according to the third embodiment;

FIG. 21 is a diagram illustrating a state during manufacturing in the method of manufacturing the transformer element according to the third embodiment;

FIG. 22 is a cross-sectional view illustrating the transformer element of the third embodiment;

FIG. 23 is a flowchart illustrating the method of manufacturing the transformer element according to the first embodiment;

FIG. 24 is a flowchart illustrating the method of manufacturing the transformer element according to the second embodiment; and

FIG. 25 is a flowchart illustrating the method of manufacturing the transformer element according to the third embodiment.

### DESCRIPTION OF THE PREFERRED EMBODIMENTS

In the description to be made, even though terms indicating specific directions such as “upper” and “lower”, may be used, these terms are for promoting the understanding of the contents of the embodiments; therefore, they do not limit the directions at the time of manufacturing or the time of using of the transformer element or the semiconductor device.

### A. First Embodiment

### A-1. Configuration

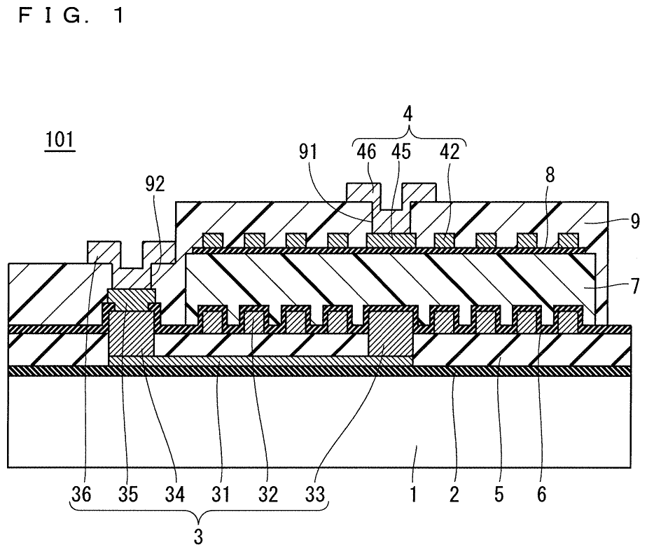

FIG. 1 is a diagram illustrating a part of a semiconductor device of the first embodiment, and is a cross-sectional view illustrating a transformer element 101 included in the semiconductor device.

The transformer element 101 includes an insulating film 2, a coil module 3, a coil module 4, an insulating film 5, an insulating film 6, an insulating film 7, an insulating film 8, and an insulating film 9. A film including the insulating film 6, the insulating film 7, and the insulating film 8 is an example of a first insulating film, and the insulating film 9 is an example of a second insulating film.

The transformer element 101 is formed on a substrate 1, as illustrated in FIG. 1. The transformer element 101 may include the substrate 1.

The coil module 3 includes a wiring 31, a coil 32 (an example of a first coil), a contact 33, a pad 34, a pad 35, and a pad 36. The coil 32, being a planar coil, is a spiral coil as well.

The coil module 4 includes a coil 42 (an example of a second coil), a pad 45 (an example of a first pad), and a pad 46 (an example of a second pad). The coil 42, being a planar coil, is a spiral coil as well.

The substrate 1 may be a semiconductor substrate using a semiconductor such as Si, SiC, or GaN, or may be an insulating substrate such as glass or ceramics. The semiconductor device of the first embodiment is a semiconductor device, for example, in which the substrate 1 is a semiconductor substrate and a semiconductor element is formed on a portion of the substrate 1 other than the portion illustrated in FIG. 1.

The insulating film 2 is provided on the substrate 1.

The wiring 31 is provided on the insulating film 2.

The insulating film 5 is provided on the insulating film 2 and the wiring 31.

The contact 33 and the pad 34 are provided on wiring 31, respectively. The contact 33 and the pad 34 respectively protrude above the upper surface of the insulating film 5.

The coil 32 is provided on the insulating film 5.

The pad 34 is connected to one end on the center side of the coil 32, which is a spiral coil, via the wiring 31 and the contact 33.

The insulating film 6 is provided on the insulating film 5, the coil 32, and the contact 33.

The pad 34 is partially covered with the insulating film 6. The pad 35 is provided on a portion of pad 34 without the insulating film 6 covering thereof.

The insulating film 7 is provided on the insulating film 6. The insulating film 7 is provided on a region overlapping with the coil 32 in plan view. The insulating film 7 is not provided on a region overlapping with the pad 35 in plan view.

The insulating film 8 is provided on the insulating film 7.

The coil 42 and the pad 45 is provided on the insulating film 8. The coil 42 and the coil 32 are opposite to each other with the insulating film 6, the insulating film 7, and the insulating film 8 interposed therebetween.

The pad 45 is connected to one end side of the coil 42. The pad 45 is connected to one end on the center side of the coil 42, which is a spiral coil.

The insulating film 9 is provided on the insulating film 8 and the coil 42 so as to cover the coil 42. The insulating film 9 protects the surface of the transformer element 101. The pad 46 is provided on the pad 45. The aggregate thickness of the pad 46 and the pad 45 is greater than the thickness of the coil 42. The insulating film 9 is, for example, a polyimide film.

An opening 91 is provided in the insulating film 9 at a position that at least partially overlaps with the pad 45 in plan view. The pad 45 is at least partially not covered with the insulating film 9.

An opening 92 is provided in the insulating film 9 at a position that at least partially overlaps with the pad 35 in plan view. The pad 35 is at least partially not covered with the insulating film 9.

The insulating film 2, the insulating film 5, and the insulating film 6 are each, for example, an oxide film or a nitride film typically used in semiconductor devices. For the insulating film 2, the insulating film 5, and the insulating film 6, films formed using the same material, or films formed using different materials may be adoptable.

The coil 32 is, for example, a primary coil, and coil 42 is, for example, a secondary coil. The magnetic coupling between the coil 32 and the coil 42 establishes signal transmission between a circuit electrically connected to the coil 32 and a circuit electrically connected to the coil 42.

A high voltage may be applied to the coil 32 and the coil 42, in which case a high potential difference causes between the coil 32 and the coil 42. The breakdown voltage of the transformer element 101 is adjustable by coordinating the configuration of the insulating film 7 provided between the coil 32 and the coil 42. For example, by thickening the insulating film 7, the breakdown voltage of the transformer element 101 can be increased.

The insulating film 7 is, for example, an organic insulating film The organic insulating film is, for example, a polyimide film.

The insulating film 8 provided on the insulating film 7 is preferably a film formed using a material different from the material of the insulating film 7, such as an oxide film or a nitride film.

Signal exchange between the coil module 3 and the outside of the transformer element 101 is implemented via wires connected to the pad 36.

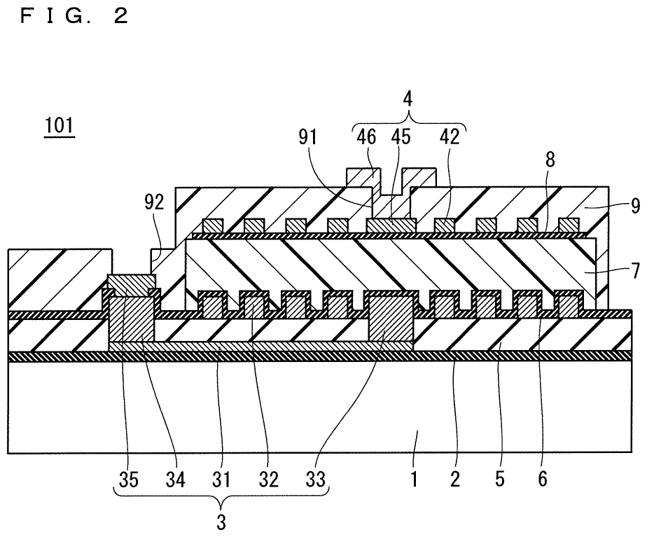

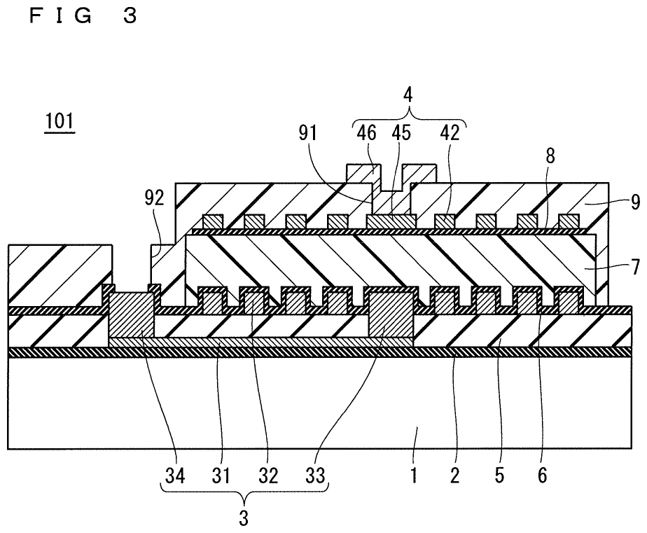

The coil module 3 may not be provided with the pad 36 as illustrated in FIG. 2, or may not be provided with the pad 35 and the pad 36 as illustrated in FIG. 3.

The pad 36 has the dimensions larger than the opening 92 provided in the insulating film 9 in plan view. The pad 36 overlaps with the entire opening 92 in plan view, for example. The pad 36 at least partially covers the insulating film 9. The pad 36 covers, for example, the edge of the opening 92 of the insulating film 9 in the entire circumferential direction of the edge of the opening 92.

The pad 46 has the dimensions larger than the opening 91 provided in the insulating film 9 in plan view. The pad 46 overlaps with the entire opening 91 in plan view, for example. The pad 46 at least partially covers the insulating film 9. The pad 46 covers, for example, the edge of the opening 91 of the insulating film 9 in the entire circumferential direction of the edge of the opening 91.

Signal exchange between the coil module 4 and the outside of the transformer element 101 is implemented via wires connected to the pad 46. The coil module 4 includes the pad 45 formed in the same process as the coil 42 is formed and the pad 46 formed in a separate process from the coil 42 is formed, and the aggregate thickness of the pad 45 and the pad 46 is thicker than the coil 42. The pad 46 may partially overlap with the coil 42 in plan view.

When performing wire bonding to the pads, the wire bonding is performed with the raised temperature and a load and ultrasonic waves being applied thereto so as to secure sufficient bonding strength between the wires and the pads. The strength of the bond between the wires and the pads is also affected by the pad thickness and bases of the pads.

In the case of the transformer element 101, the bases of the pad 34, the pad 35 and the pad 36, which are the pads of the coil module 3, are the wiring 31, the insulating film 2 and the substrate 1, and the bases of the pad 45 and the pad 46, which are the pads of the coil module 4, are the insulating film 8 and the insulating film 7 being a thick film. The bond strength by the wire bonding to the pads of the coil module 3 is greatly affected by the substrate 1. The bond strength by the wire bonding to the pads of the coil module 4 is greatly affected by the insulating film 7.

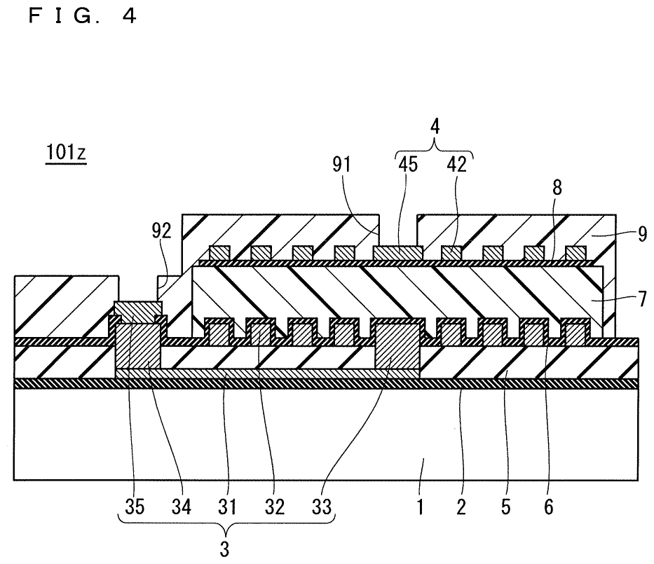

FIG. 4 is a cross-sectional view illustrating a transformer element 101z of a comparative example. The transformer element 101z is similar to the transformer element 101 except that the pad 46 and the pad 36 are not provided therein. In the transformer element 101z, the pad provided in the coil module 4 is the pad 45 formed in the same process as the coil 42 is formed, and the thickness of the pad 45 is substantially the same as the thickness of the coil 42.

The insulating film 7 is an organic insulating film and is softer than the substrate 1, which is a semiconductor substrate or the like, therefore, in the transformer element 101z, when wire bonding to the pad of the coil module 3 and wire bonding to the pad of the coil module 4 are performed under the same conditions, the bond strength of the coil module 4 is lower. In other words, if wire bonding to the pad of the coil module 4 is performed under the condition where wire bonding to the pad of the coil module 3 is properly performed in the transformer element 101z, the bonding strength of the wire bonding to the pad of the coil module 4 is insufficient.

On the other hand, if the wire bonding to the pad of the coil module 3 is performed under the condition where the wire bonding to the pad of the coil module 4 is properly performed, excessive load is applied to the pad of the coil module 3, causing cracks in the wiring 31 or the insulating film 2 being the base of the pad, and lowering the reliability of the transformer element 101z.

It is also conceivable in the transformer element 101z that the bonding to the pad of the coil module 4 is properly performed under the same conditions as the bonding to the pad of the coil module 3 by thickening the coil 42 and pad 45. For example, an experiment showed that it has been confirmed that the bonding strength of wire bonding of the coil module 4 to the pad is sufficient by setting the thickness of the pad 45 to 8 μm or more when the insulating film 7 is made of polyimide. However, in the transformer element 101z, in order to increase the thickness of the pad 45, the coil 42 must be thickened as well. In order to increase the thickness of the coil 42, widening the radial interval of the spiral shape of the coil 42 is required, or the line width of the spiral shape of the coil 42 may become thin during processing. Therefore, in the transformer element 101z, there is a problem that when the pad 45 is made thicker, the space efficiency of the coil 42 is deteriorated and the electrical characteristics of the coil 42 is deteriorated.

The transformer element 101 of the first embodiment includes the pad 45 formed in the same process as the coil 42 is formed, and the pad 46 formed in a process different from that of coil 42; therefore, the pads of the coil module 4 can be formed thick as a whole without thickening the coil 42, and the pads of the coil module 4 can be thickened while suppressing the influence on the characteristics of the coil 42. For example, even if the pads of the coil module 4 are thickened, the space efficiency of the coil 42 does not deteriorate. In addition, the transformer element 101 is advantageous in that, even if it is required to change the wire bonding conditions with the film thickness or material of the insulating film 7 having changed, such a change is dealt with simply changing the film thickness of the pad 46 without changing the configuration of the coil 42. The aggregate thickness of the pad 45 and the pad 46 is, for example, 8 μm or more.

Wire-bonding to pad is performed with a wire-bonding tool being pressed against the pad, and the pad must be larger than the wire-bonding tool. The pad 46, which, at least, partially covers the insulating film 9, is provided; therefore, the required pad size is secured for wire bonding with only the size of the pad 46 increasing without changing the arrangement area of the coil 42.

### A-2. Manufacturing Method

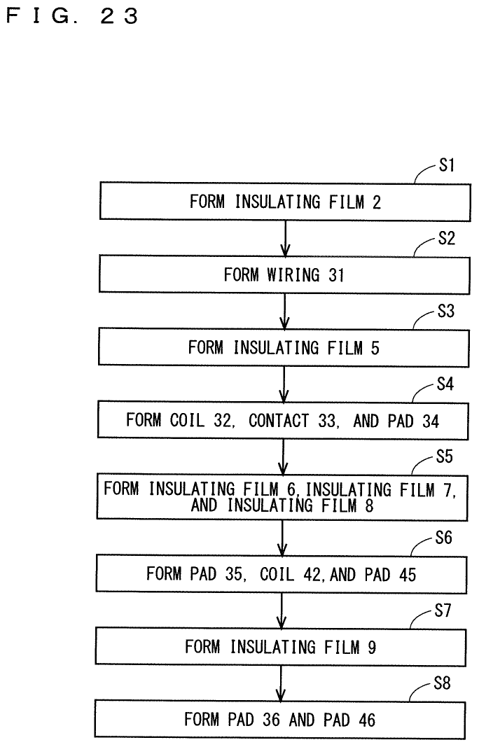

FIG. 23 is a flowchart illustrating the method of manufacturing the transformer element according to the present embodiment. The method of manufacturing the transformer element according to the present embodiment includes Steps S1 to S8.

First, the insulating film 2 is formed on the substrate 1 in Step S1. The insulating film 2 may be any material as long as it can electrically insulate the substrate 1 from the coil module 3 and the coil module 4. The insulating film 2 is, for example, an oxide film or a nitride film, however, other films may be adoptable as long as insulation can be secured.

Next, the wiring 31 is formed on the insulating film 2 in Step S2. In Step S2, a conductive film is formed on the insulating film 2 using a vacuum deposition method, a chemical vapor deposition method, a sputtering method, or the like, and then, the wiring 31 is formed by processing the conductive film into a desired pattern using a photolithography technique and an etching technique. The conductive film formed on the insulating film 2 may be any of a film of metal such as gold or aluminum, a low-resistance semiconductor film, or a conductive organic film.

Next, in Step S3, the insulating film 5 is formed on the insulating film 2 and the wiring 31. In Step S3, the insulating film 5 is formed so as to have openings at positions where the contact 33 and the pad 34 are formed.

Next, in Step S4, the coil 32, the contact 33 and the pad 34 are formed. In Step S4, a conductive film is formed using a vacuum deposition method, a chemical vapor deposition method, a sputtering method, or the like, and the coil 32, the contact 33, and the pad 34 are formed by processing the conductive film into a desired pattern using a photolithography technique and an etching technique.

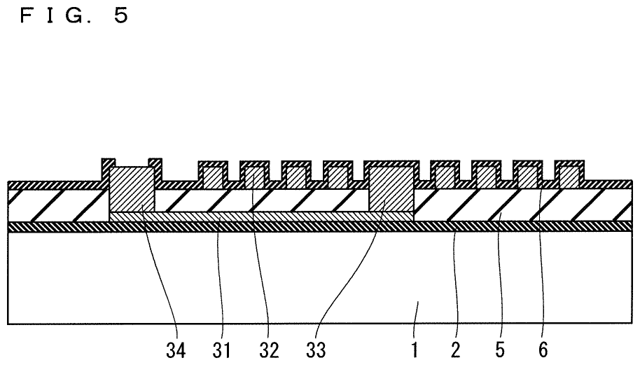

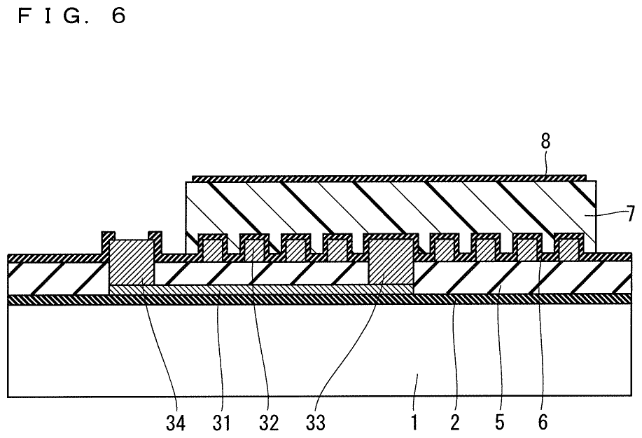

Next, in Step S5, the insulating film 6, the insulating film 7, and the insulating film 8, which are inter-coil insulating films, are formed. In Step S5, first, the insulating film 6 is formed on the insulating film 5, the coil 32, the contact 33, and the pad 34, and then an opening is provided in the insulating film 6 so that the pad 34 is partially exposed from the insulating film 6 (see FIG. 5). In Step S5, next, the insulating film 7 is formed using polyimide, which is an organic material, for example. The insulating film 7 is formed to cover the coil 32. In Step S5, the insulating film 8 is then formed on the insulating film 7. The insulating film 8 is formed in a region where the coil module 4 is to be formed in a later process (see FIG. 6).

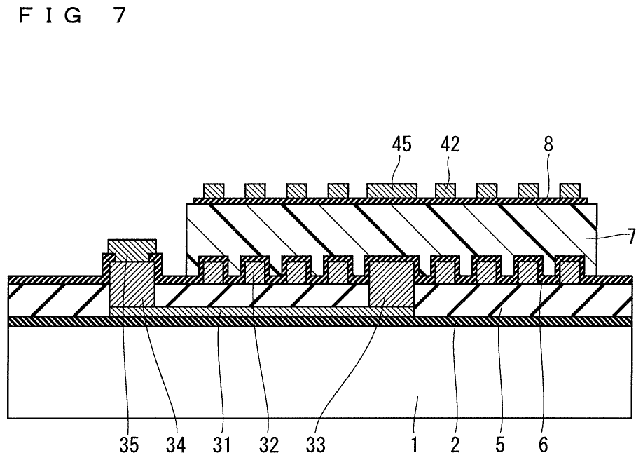

Next, in Step S6, a conductive film is formed, and then, the conductive film is processed to form the pad 35, the coil 42, and the pad 45 (see FIG. 7). Dry etching may be adopted as a method for processing the conductive film in Step S6. In the dry etching, the insulating film 8 functions as a protective film for the etching bottom surface, and etching of the insulating film 7 is suppressed. If there is no problem even without the pad 35 from the viewpoint of the influence on the wire bonding and the influence on the electrical characteristics, the pad 35 may not be provided.

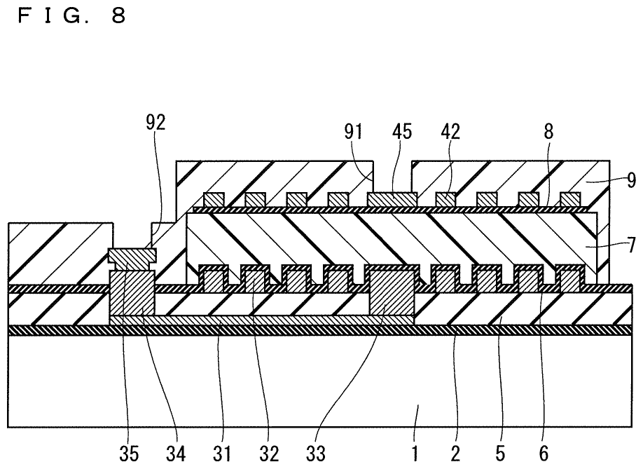

Next, in Step S7. the insulating film 9 is formed to protect the surface of the transformer element 101 (see FIG. 8). An opening 91 is formed in the insulating film 9 so that the pad 45 is at least partially exposed from the insulating film 9, and an opening 92 is formed so that the pad 35 is at least partially exposed from the insulating film 9. The opening 91 and the opening 92 may be formed by exposure and development using photosensitive polyimide, or the opening 91 and the opening 92 may be formed by etching using a resist as a mask material.

Next, in Step S8, the pad 36 and the pad 46 are formed.

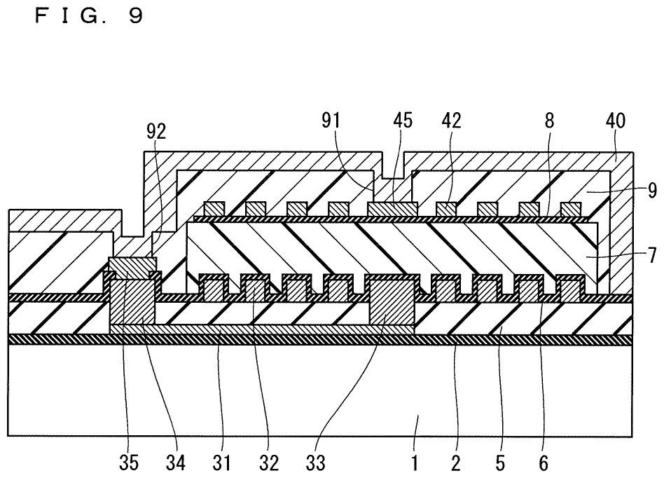

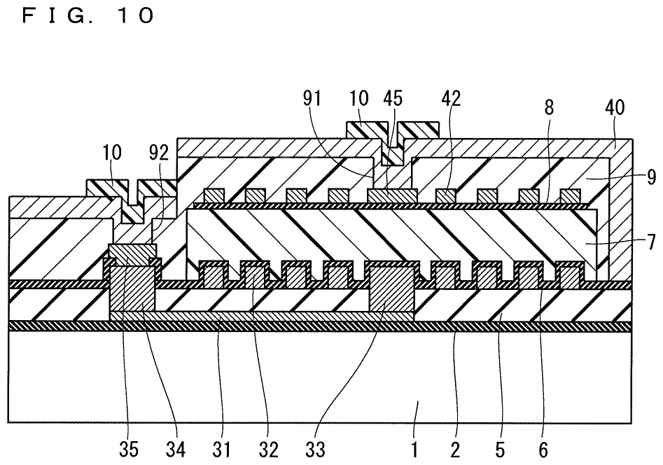

In Step S8, first, a conductive film 40 is formed on the insulating film 9 (see FIG. 9), and then a resist 10 is formed on the conductive film 40 (see FIG. 10). The conductive film 40 is formed so as to contact the pad 45 through the opening 91 and contact the pad 35 through opening 92. A resist 10 is formed at a position overlapping with the opening 91 in plan view with the dimensions larger than the opening 91 and another resist 10 is also formed at a position overlapping with the opening 92 in plan view with dimensions larger than the opening 92. That is, the resists 10 are formed so as to overlap the insulating film 9 in plan view. And, the conductive film 40 is etched using the resists 10 as a mask to form the pad 36 and the pad 46. Although, the etching to be adopted may be dry etching or wet etching, wet etching is desirable from the viewpoint of inflicting less damage to the insulating film 9. The resist 10 is formed so as to overlap the insulating film 9 in a plan view with the dimensions larger than the opening 91 or the opening 92, etching of the pad 35 or the pad 45 is suppressed, thereby, leading to the suppression of disconnection or variations in electrical characteristics caused by the pad 35 or the pad 45 being thinned. Further, when the material of the pad 46 is different from the material of the pad 45, that is, when the material of the conductive film 40 is different from the material of the pad 45, etching of the pad 45 in the etching of the conductive film 40 is suppressed, thereby, leading to the suppression of disconnection or variations in electrical characteristics caused by the pad 45 being thinned.

The transformer element 101 illustrated in FIG. 1 is formed through the process described above.

As described above, in the method of manufacturing the transformer element of the first embodiment, the coil 42 is formed on the insulating film 8 and then the insulating film 9 is formed on the insulating film 8 and the coil 42 such that the coil 42 is covered and the pad 45 is not covered at least partially, and after forming the insulating film 9 the pad 46 is formed on the pad 45.

It is also possible to form the pad 46 and the pad 36 from the state illustrated in FIG. 8, by forming a conductive film on the pad 45 and the pad 35 by plating.

The semiconductor device of the first embodiment is manufactured by using a semiconductor substrate as the substrate 1 and forming the transformer element 101 on the substrate 1 by the above-described method of manufacturing the transformer element of the first embodiment.

### B. Second Embodiment

### B-1. Configuration

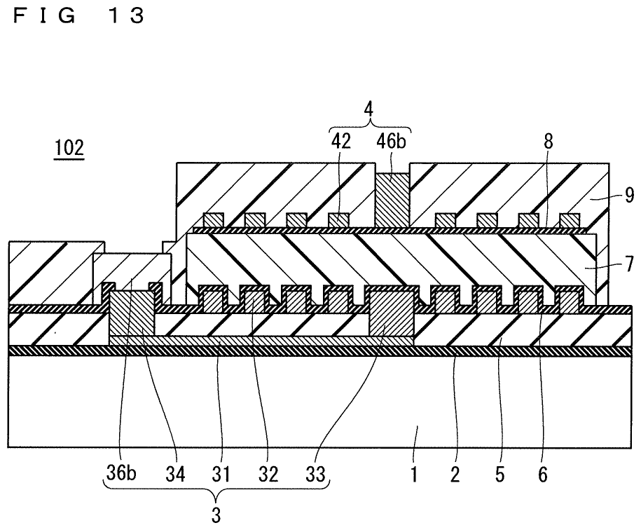

FIG. 13 is a diagram illustrating a part of a semiconductor device of a second embodiment, and is a cross-sectional view illustrating a transformer element 102 included in the semiconductor device.

A coil module 3 in the transformer element 102 is different from the coil module 3 in the transformer element 101 in that, instead of the pad 35 and the pad 36, a pad 36b is provided therein. A coil module 4 in the transformer element 102 is different from the coil module 4 in transformer element 101 in that, instead of the pad 45 and the pad 46, a pad 46b is provided therein. In other respects, the transformer element 102 is similar to the transformer element 101.

The pad 46b is thicker than the coil 42. The pad 46b is thick enough for proper wire bonding. That is, the thickness of pad 46b is equivalent to the aggregate thickness of the pad 45 and the pad 46 in the first embodiment.

### B-2. Manufacturing Method

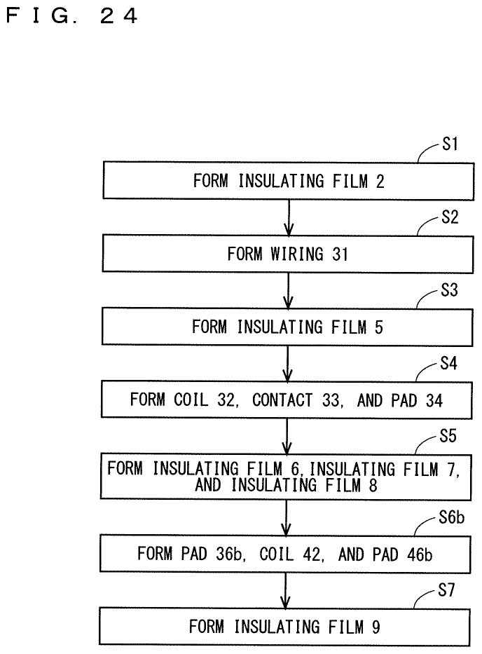

FIG. 24 is a flowchart illustrating the method of manufacturing the transformer element according to the second embodiment. The method of manufacturing the transformer element according to the second embodiment includes Steps S1 to S5, Step S6b, and Step S7.

Steps S1 to S5 in the method of manufacturing the semiconductor device of the second embodiment are the same as Steps S1 to S5 in the method of manufacturing the transformer element 101 in the first embodiment.

After Step S5, in Step S6b, the pad 36b, the pad 46b, and the coil 42 are formed from the state illustrated in FIG. 6 after Step S5.

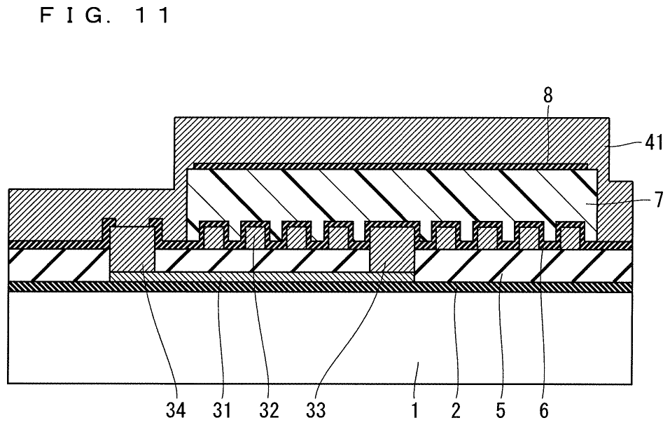

In Step S6b, first, a conductive film 41 is formed as illustrated in FIG. 11. At this point, the conductive film 41 is formed so as to have the same thickness as the pad 46b, for example. Next, the portions where the pad 36b and the pad 46b are to be formed are masked with the resists, and the conductive film 41 is etched (see FIG, 12). The etching thins the portion of the conductive film 41 other than the portion to be the pad 36b and the portion to be the pad 46b. Next, the conductive film 41 is further processed using the photolithography technique, the etching technique, or the like to form the pad 36b, the pad 46b, and the coil 42.

Next, the insulating film 9 for surface protection is formed in Step S7. The method of forming the insulating film 9 is the same as that in the first embodiment.

The transformer element 102 illustrated in FIG. 13 is formed through the process described above.

The pad 46b being thick improves the bonding strength in wire bonding to the pad 46b. The pad 46b is thicker than the coil 42; therefore, even if the pad 46b is thickened so as to obtain sufficient bonding strength in wire bonding to the pad 46b, the influence on the characteristics of the coil 42 is suppressed.

In the manufacturing method of the semiconductor device of the second embodiment, the conductive film 41 to be the coil 42 and the pad 46b is formed on the insulating film 8, and then the conductive film 41 is partially removed to form the coil 42 and the pad 46b. Therefore, the formation of the conductive film for forming the coil module 4 needs to be performed only once, improving the production efficiency.

The semiconductor device of the second embodiment is manufactured by using a semiconductor substrate as the substrate 1 and forming the transformer element 102 on the substrate 1 by the above-described method of manufacturing the transformer element of the second embodiment.

### C. Third Embodiment

### C-1. Configuration

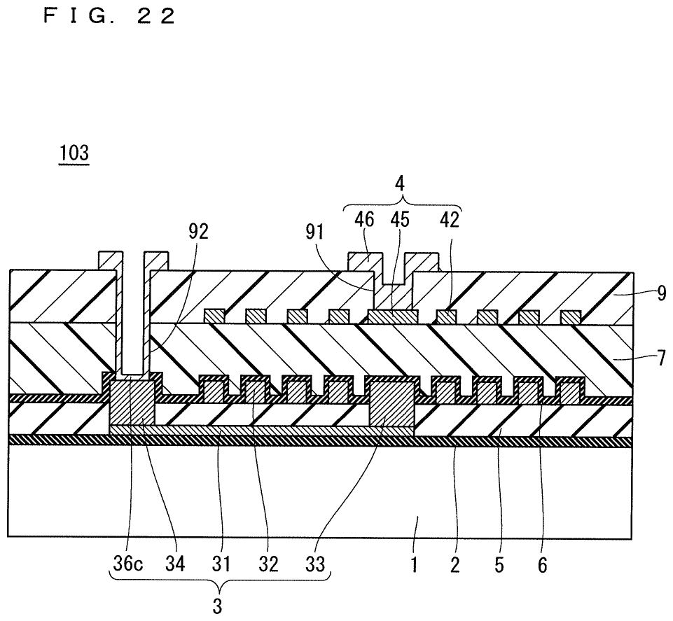

FIG. 22 is a diagram illustrating a part of a semiconductor device of a third embodiment, and is a cross-sectional view illustrating a transformer element 103 included in the semiconductor device. A transformer element 103 is different from the transformer element 101 in that the insulating film 7 and the insulating film 9 are provided, not only in a portion where the coil 32 is formed, but also in a portion where the pad 34 is formed. Further, in the transformer element 103, instead of the pad 35 and the pad 36, a pad 36c is provided as compared with the transformer element 101. The insulating film 8 is not provided in the transformer element 103. In other respects, the transformer element 103 is similar to the transformer element 101.

In the transformer element 103 as well, the pad 46 is provided on the pad 45 as in the case of the transformer element 101 of the first embodiment. The aggregate thickness of the pad 46 and the pad 45 is greater than the thickness of the coil 42. The pad 46 has the dimensions larger than the opening 91 provided in the insulating film 9 in plan view. The pad 46 overlaps the entire opening 91 in plan view. The pad 46 at least partially covers the insulating film 9. The pad 46 covers, for example, the edge of the opening 91 of the insulating film 9 in the entire circumferential direction of the edge of the opening 91.

The pad 36c has the dimensions larger than the opening 92 provided in the insulating film 7 and the insulating film 9 in plan view. The pad 36c overlaps the entire opening 92 in plan view. The pad 36c at least partially covers the insulating film 9. The pad 36c covers, for example, the edge of the opening 92 of the insulating film 9 in the entire circumferential direction of the edge of the opening 92.

### C-2. Manufacturing Method

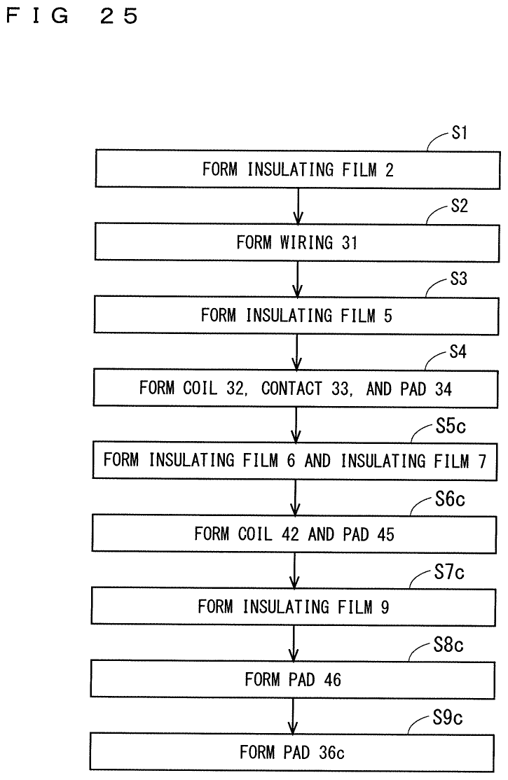

FIG. 25 is a flowchart illustrating the method of manufacturing the transformer element according to the third embodiment. The method of manufacturing the transformer element according to the third embodiment includes Steps S1 to S4 and Steps S5c to S9c.

Steps S1 to S4 in the method of manufacturing the semiconductor device of the third embodiment are the same as Steps S1 to S4 in the method of manufacturing the transformer element 101 in the first embodiment.

In Step S5c, first, an insulating film 6 is formed in the same manner as in Step S5 in the manufacturing method of the semiconductor device of the first embodiment (see FIG. 5).

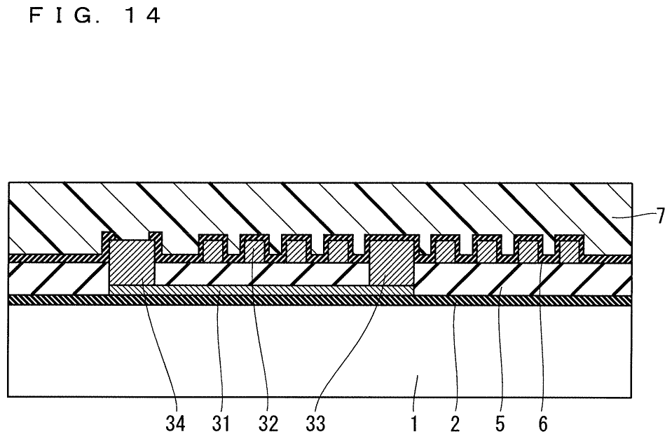

In Step S5c, next, an insulating film 7 is formed from the state of FIG. 5 (see FIG. 14). Although in Step S5c, the insulating film 7 is formed, the process to the insulating film 7 is not performed. Therefore, the insulating film 7 is also formed in a portion other than the portion covering the coil 32 after the completion of Step S5c, for example, the insulating film 7 is also formed in a position overlapping with the pad 34 in plan view.

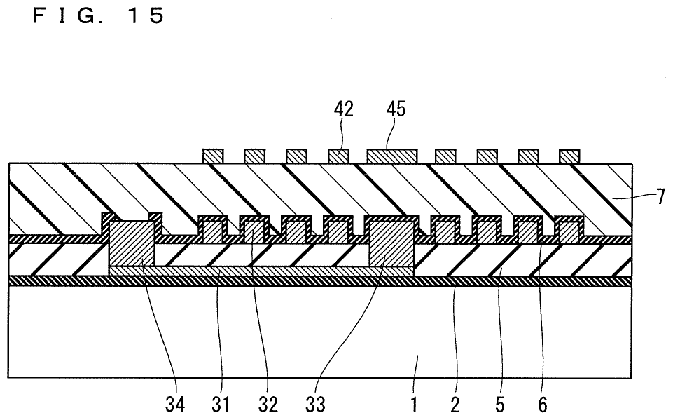

Next, in Step S6c, the coil 42 and the pad 45 are formed on the insulating film 7 by a method similar to that described in the first embodiment (see FIG. 15). Although in the first embodiment, the configuration has been illustrated in which the insulating film 8 is provided on the insulating film 7, the insulating film 8 may be omitted as long as there is no problem from the viewpoint of the influence on the electrical characteristics even without the insulating film 8 when the coil 42 and the pad 45 are formed.

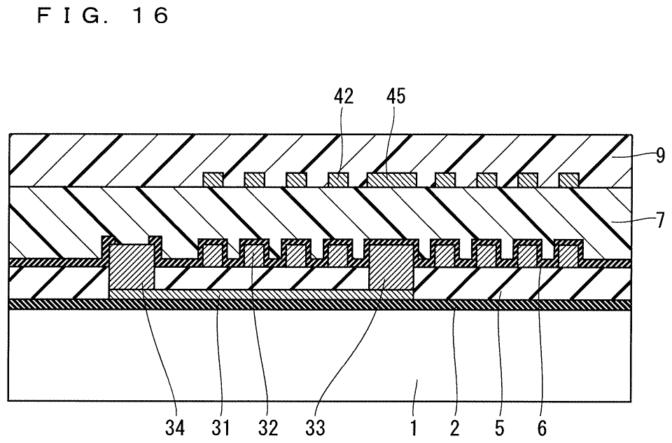

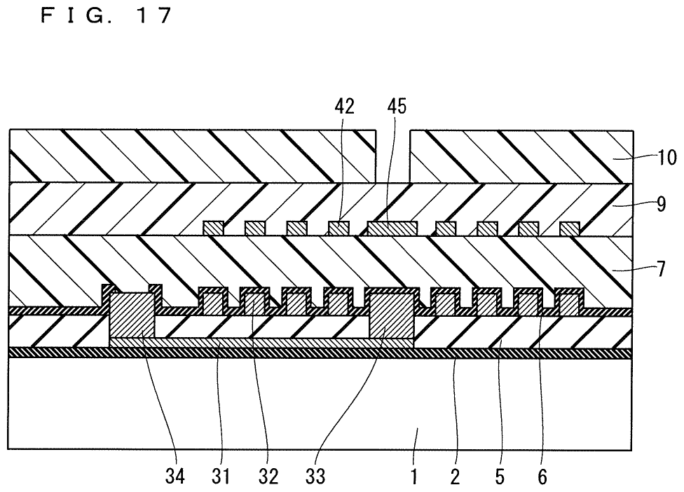

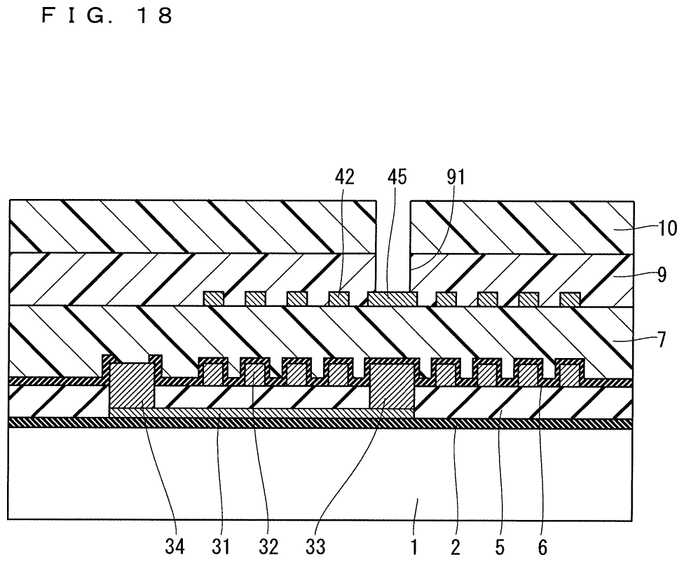

Next, the insulating film 9 is formed in Step S7c. In Step S7c, first, the insulating film 9 is formed as illustrated in FIG. 16, and then the resist 10 is formed in a desired pattern as illustrated in FIG. 17, and the insulating film 9 is etched using the resist 10 as a mask to form an opening 91 (see FIG. 18). The opening 91 is formed so that the pad 45 is exposed from the insulating film 9.

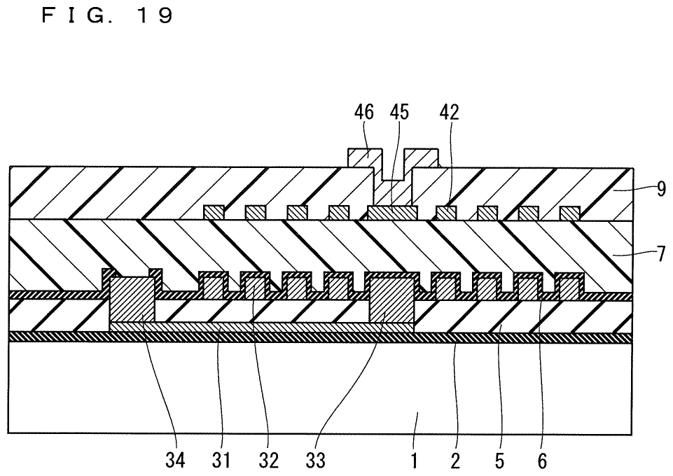

Next, in Step S8c, the pad 46 is formed on the pad 45 (see FIG. 19). The pad 46 is formed by a method similar to that described in the first embodiment. The pad 46 is formed so as to at least partially cover the insulating film 9. The pad 46 is formed so as to, for example, cover the edge of the opening 91 of the insulating film 9 in the entire circumferential direction of the edge of the opening 91.

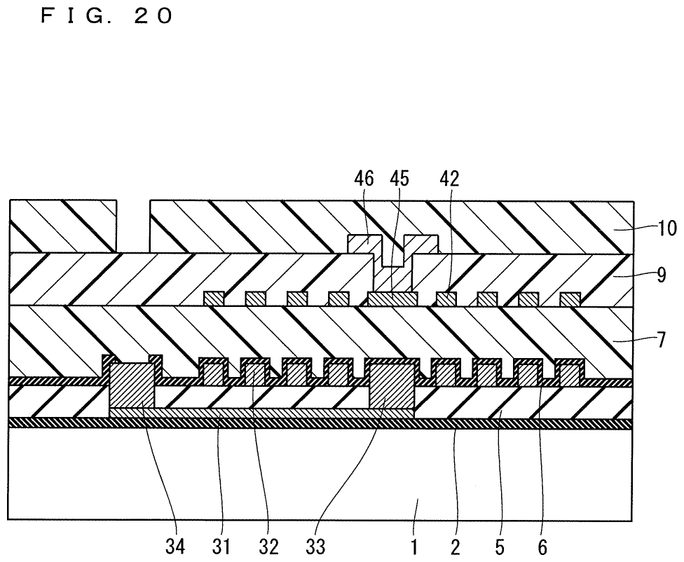

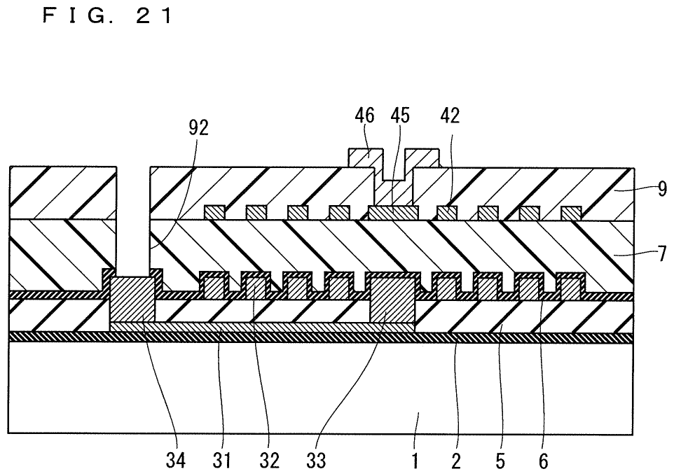

Next, in Step S9c, the pad 36c is formed. In Step S9c, the resist 10 is formed on the insulating film 9 (see FIG. 20), the insulating film 7 and the insulating film 9 are partially removed by etching using the resist 10 as a mask, and the opening 92 is formed such that the pad 34 is exposed (see FIG. 21). Then, the pad 36c is formed so as to pass through the opening 92 and be in contact with the pad 34.

The transformer element 103 illustrated in FIG. 22 is formed through the process described above,

In the method of manufacturing the transformer element of the third embodiment, processing proceeds to the state illustrated in FIG. 21 in a state where there is no step in the insulating film 7, this allows the manufacture of a semiconductor device without using specific manufacturing equipment or manufacturing methods for dealing with large steps. Therefore, the cost of capital investment and the cost of setting conditions can be lowered and the time required therefor is shortened, ensuring the reduction in the processing cost and manufacturing cost.

The semiconductor device of the third embodiment is manufactured by using a semiconductor substrate as the substrate 1 and forming the transformer element 103 on the substrate 1 by the above-described method of manufacturing the transformer element of the third embodiment.

The embodiments can be combined, appropriately modified or omitted, without departing from the scope of the disclosure.

While the disclosure has been illustrated and described in detail, the foregoing description is in all aspects illustrative and not restrictive. It is therefore understood that numerous modifications and variations can be devised without departing from the scope of the invention.

What is claimed is:

1. A transformer element comprising:
a first coil having a planner shape;
a first insulating film provided on an upper side of the first coil;
a second coil having a planner shape and opposite to the first coil and provided on the first insulating film;
a first pad provided on the first insulating film and connected to a side of one end of the second coil;
a second pad provided on the first pad; and
a second insulating film provided on the first insulating film and the second coil so as to cover the second coil, wherein
an aggregate thickness of the first pad and the second pad is thicker than the second coil, and
the second pad at least partially covers the second insulating film.

2. The transformer element according to claim 1, wherein
the first coil and the second coil are spiral coils, and
the one end of the second coil is an end on a center side of the spiral coil. 3. The transformer element according to claim L wherein
the second insulating film has an opening at a position overlapping with the first pad in plan view,
the second pad overlaps the opening entirely in plan view.
the second pad is in contact with the first pad so as to pass through the opening, and
the second pad covers an edge of the opening of the second insulating film in an entire circumferential direction of the edge of the opening.

4. The transformer element according to claim 1, wherein
a material of the first pad is different from a material of the second pad.

5. The transformer element according to claim 1, wherein
the first insulating film includes an organic insulating film. 6. The transformer element according to claim 5, wherein
the organic insulating film is a polyimide film.

7. A semiconductor device comprising
a semiconductor substrate and a transformer element according to claim 1 provided on the semiconductor substrate.

8. A method of manufacturing a transformer element, wherein
the transformer element includes
a first coil having a planner shape,
a first insulating film provided on an upper side of the first coil,
a second coil having a planner shape and opposite to the first coil and provided on the first insulating film,
a first pad provided on the first insulating film and connected to a side of one end of the second coil,
a second pad provided on the first pad, and
a second insulating film provided on the first insulating film and the second coil so as to cover the second coil, the method comprising:
forming the second coil on the first insulating film, and then forming the second insulating film on the first insulating film and the second coil such that the second coil is covered and the first pad is not covered at least partially; and
forming the second pad on the first pad after forming the second insulating film.

9. The method of manufacturing the transformer element according to claim 8, wherein
the forming of the second pad is performed by plating.

10. The method of manufacturing the transformer element according to claim 8, wherein
the transformer element includes a third pad connected to a side of one end of the first coil, the method comprising:
forming the first coil;
forming the first insulating film on the first coil and the third pad;
forming the second coil on the first insulating film; and
partially removing the first insulating film to expose the third pad after forming the second coil.

11. The method of manufacturing the transformer element according to claim 10, wherein,
after the forming of the first insulating film, no process is performed on the first insulating film before the formation of the second coil.

12. A method of manufacturing a transformer element, wherein
the transformer element includes
a first coil having a planner shape,
an insulating film provided on an upper side of the first coil,
a second coil having a planner shape and opposite to the first coil and provided on the insulating film, and
a pad provided on the insulating film and connected to a side of one end of the second coil,
the pad is thicker than the second coil, the method comprising
forming a conductor film to be the second coil and the pad on the insulating film; and then
forming the second coil and the pad by partially removing the conductor film.

13. A method of manufacturing a semiconductor device, wherein
the semiconductor device includes a semiconductor substrate and a transformer element provided on the semiconductor substrate, the method comprising
using the method of manufacturing the transformer element according to claim 8, manufacturing the transformer element on the semiconductor substrate.

14. A method of manufacturing a semiconductor device, wherein
the semiconductor device includes a semiconductor substrate and a transformer element provided on the semiconductor substrate, the method comprising
using the method of manufacturing the transformer element according to claim 12, manufacturing the transformer element on the semiconductor substrate.
